(19) United States
(12) Patent Application Publication
(10) Pub. No.: US 2025/0264530 A1
(43) Pub. Date: Aug. 21, 2025

(54) DISTRIBUTING SELECT GATE SCAN ACROSS ERASE CYCLES

(71) Applicant: Micron Technology, Inc., Boise, ID (US)

(72) Inventors: Hui Ye, Shanghai (CN); Hui Zhu, Shanghai (CN); Jian Hui Gao, Shanghai (CN); Zeng Li, Shanghai (CN); Yutong Lin, Shanghai (CN); Shenghao Xu, Shanghai (CN)

(21) Appl. No.: 19/054,497

(22) Filed: Feb. 14, 2025

Related U.S. Application Data
(60) Provisional application No. 63/555,247, filed on Feb. 19, 2024.

(51) Int. Cl. G01R 31/3185

(52) U.S. Cl. CPC G01R 31/318544

(57) ABSTRACT

The disclosure configures a memory sub-system controller to distribute memory operations across multiple program-erase (PE) cycles. The controller determines that an individual portion of a set of memory components satisfies a degradation criterion. The controller applies a memory operation on a first group of regions of a plurality of regions of the individual portion to test reliability of the first group of regions as part of performing a first PE cycle on the individual portion. The controller applies the memory operation on a second group of regions of the plurality of regions to test reliability of the second group of regions as part of performing a second PE cycle on the individual portion and selectively retires the individual portion based on results of testing the reliability of the first group of regions and the second group of regions across the first PE cycle and the second PE cycle.

### PRIORITY APPLICATION

This application claims the benefit of priority to U.S. Provisional Application Ser. No. 63/555,247, filed Feb. 19, 2024, which is incorporated herein by reference in its entirety.

### TECHNICAL FIELD

Examples of the disclosure relate generally to memory sub-systems and, more specifically, to providing adaptive media management for memory components, such as memory dies.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data on the memory components and to retrieve data from the memory components.

### BRIEF DESCRIPTION OF THE DRAWINGS

The present disclosure will be understood more fully from the detailed description given below and from the accompanying drawings of various examples of the disclosure.

FIG. 1 is a block diagram illustrating an example computing environment including a memory sub-system, in accordance with some examples of the present disclosure.

FIG. 2 is a block diagram of an example table used to perform adaptive media management operations, in accordance with some implementations of the present disclosure.

FIG. 3 is a block diagram of an example of a timing diagram of the adaptive media management operations, in accordance with some implementations of the present disclosure.

FIG. 4 is a flow diagram of an example method of performing adaptive media management operations, in accordance with some implementations of the present disclosure.

FIG. 5 is a block diagram illustrating a diagrammatic representation of a machine in the form of a computer system within which a set of instructions can be executed for causing the machine to perform any one or more of the methodologies discussed herein, in accordance with some examples of the present disclosure.

### DETAILED DESCRIPTION

Examples of the present disclosure configure a system component, such as a memory sub-system controller, to perform one or more memory operations (e.g., select gate (SG) scan operations) that test reliability of memory components across multiple program-erase (PE) cycles. For example, the controller divides regions of an individual portion of a set of memory components (e.g., a block stripe) into multiple groups. When a PE cycle is performed on the individual portion (e.g., based on a garbage collection operation), the controller performs the one or more memory operations on a first group of the regions of the individual portion without performing the one or more memory operations on a second group. Then, when another PE cycle is later performed on the individual portion (e.g., after data is stored and needs to be erased), the controller performs the one or more memory operations on the second group of the regions of the individual portion without performing the one or more memory operations on the first group. This way, the one or more memory operations are performed on each of the groups regions of the individual portion across many PE cycles which allows the garbage collection operations and erase operations to be completed faster and more efficiently. In this way, the controller can improve the storage and retrieval of data from the memory components and reduce errors.

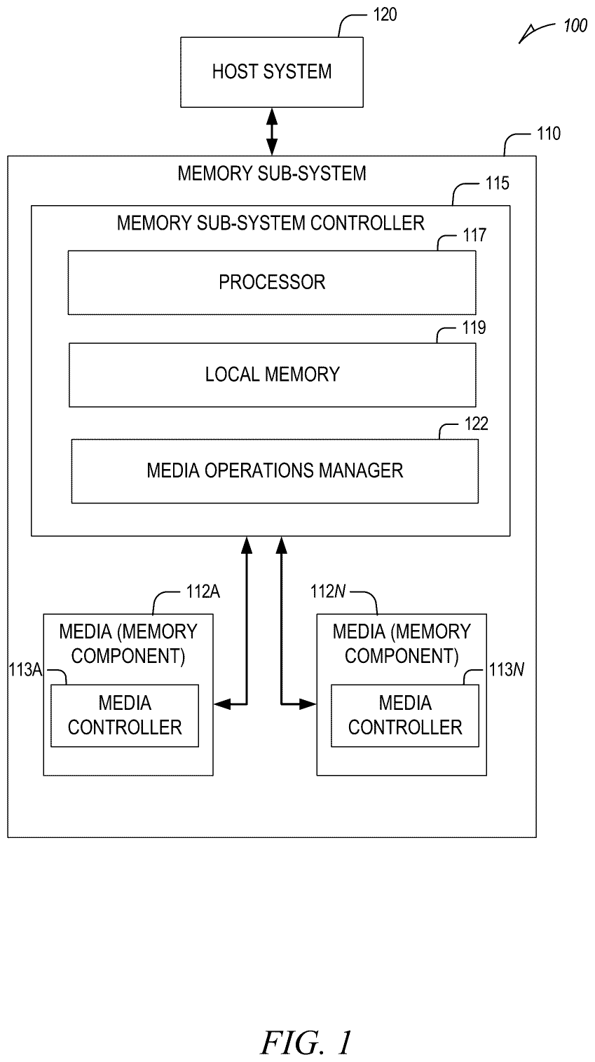

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data.”

The memory sub-system can initiate media management operations, such as a write operation, on host data that is stored on a memory device. For example, firmware of the memory sub-system may re-write previously written host data from a location on a memory device to a new location as part of garbage collection management operations. The data that is re-written, for example as initiated by the firmware, is hereinafter referred to as “garbage collection data”. “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scans read all data and identify the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest area than can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which is a raw memory device combined with a local embedded controller for memory management within the same memory device package.

When certain portions of the memory components of conventional memory sub-systems start reaching their end of life, such as when a certain number (e.g., 1000) of PE cycles are performed on the portions, additional tests need to be performed to test the reliability of the portions. If the portions successfully pass the additional tests (e.g., SG scan operations), the portions are placed in a free block pool to allow data to be programmed to the portions. If the portions fail the additional tests (e.g., SG scan operations), the portions are marked bad to prevent data from being subsequently programmed to these portions. There are certain areas within each NAND block called SGD (select gate drain) and SGS (select gate source) that can have a charge loss as NAND undergoes multiple PE cycles. The SG scan operations can be performed to detect if this degradation has happened when the NAND block has reached each predefined erase cycles. In some cases, the SG scan operation can first be triggered at PE cycle count of 1000 and then gets triggered at every 200 PE cycle counts.

As part of the SG scan operations, a low VT (voltage threshold) scan is performed on the SGS/SGD of a target block to test if the scan fails. If this scan fails, a voltage recovery operation can be performed to improve the health of the memory block. Then, a high VT scan is performed on the SGS/SGD of the target block to test if the scan fails. The combination of the low VT and high VT application to the target block to determine if the target block is operating within a desired voltage range enables the detection of memory blocks that are likely to fail and provides an indication or measure of reliability of the target block as results of the SG scan operations.

In some cases, as part of performing garbage collection operations or erasing a portion of the memory components (e.g., a block stripe), the memory controllers determine whether the current PE cycle count associated with the portion corresponds to a threshold (e.g., 1000). If so, after erasing data programmed in the portion, the memory controller performs SG scan operations to test the reliability of the portion before returning the portion to the free block pool. Because the portion is made up of a significant amount of LUNs, the time it takes to complete performing the SG scan operations on all of the LUNs of the portion is substantial. This slows down the overall operation of erasing or performing garbage collection on the portion which results in inefficient operation of the memory sub-systems.

Examples of the present disclosure address the above and other deficiencies by providing a memory controller that can divide the memory operations (e.g., SG scan operations) that need to be performed on a portion of the memory components across many PE cycles. For example, when a PE cycle is performed on an individual portion, the controller performs the one or more memory operations on a first group of the regions of the individual portion without performing the one or more memory operations on a second group. Then, when another PE cycle is later performed on the individual portion (e.g., after data is stored and needs to be erased), the controller performs the one or more memory operations on the second group of the regions of the individual portion without performing the one or more memory operations on the first group. This way, the one or more memory operations are performed on each of the groups regions of the individual portion across many PE cycles which allows the garbage collection operations and/or erase operations to be completed faster and more efficiently. In this way, the controller can improve the storage and retrieval of data from the memory components and reduce errors.

In some examples, the memory controller determines that an individual portion of the set of memory components satisfies a degradation criterion, the individual portion including a plurality of regions. The memory controller applies a memory operation on a first group of regions of the plurality of regions to test reliability of the first group of regions as part of performing a first PE cycle on the individual portion. The memory controller applies the memory operation on a second group of regions of the plurality of regions to test reliability of the second group of regions as part of performing a second PE cycle on the individual portion. The memory controller selectively retires the individual portion based on results of testing the reliability of the first group of regions and the second group of regions across the first PE cycle and the second PE cycle.

In some examples, the memory controller receives a request to erase data stored in the individual portion. The memory controller obtains an PE cycle count associated with the individual portion in response to receiving the request. The memory controller determines that the PE cycle count transgresses a threshold value; and in response to determining that the PE cycle count transgresses the threshold value, determines that the individual portion satisfies the degradation criterion.

In some examples, the memory controller tracks which regions of the plurality of regions have been tested for reliability across multiple PE cycles. In some cases, the memory controller determines that the reliability of the first group of regions and the second group of regions represents failure of the first group of regions and the second group of regions. In some examples, the memory controller, in response to determining that the reliability of the first group of regions and the second group of regions represents failure, prevents data from being written to the individual portion. In some cases, the memory controller determines that the reliability of a threshold quantity of groups (e.g., more than 50 percent or more than half) of the plurality of regions represents failure, and in response to determining that the reliability of a threshold quantity of groups of the plurality of regions represents failure, prevents data from being written to the individual portion.

In some examples, the individual portion includes an individual block stripe, and wherein the plurality of regions includes a plurality of LUNs each associated with a respective collection of planes. In some examples, a first LUN of the plurality of LUNs corresponds to a first memory die, and a second LUN of the plurality of LUNs corresponds to a second memory die.

In some aspects, the memory operation is applied to the first group in response to receiving a first request to erase the individual portion. In such cases, the memory controller places the individual portion in a free block pool to allow data to be written to the individual portion in response to applying the memory operation on the first group of regions to test reliability of the first group of regions. The memory controller programs data to the individual portion that has been placed in the free block pool and receives a second request to erase the individual portion after programming the data to the individual portion that has been placed in the free block pool, the second request being received after the first request to erase the individual portion. The memory controller applies the memory operation on the second group of regions to test reliability of the second group of regions in response to receiving the request to erase the individual portion.

In some examples, the first request and the second request are generated as part of garbage collection operations. In some cases, the memory operation includes a SG scan operation. In some cases, the memory controller determines that the results of testing the reliability of the first group of regions and the second group of regions indicate that the individual portion passes the reliability. The memory controller, after performing a threshold number of additional PE cycles on the individual portion, determines that the degradation criterion is satisfied again.

In some examples, the memory controller determines that the degradation criterion of the individual portion is satisfied a first time in response to determining that a PE cycle count associated with the individual portion transgresses a first threshold value. The memory controller determines that the degradation criterion of the individual portion is satisfied a second time in response to determining that an updated PE cycle count associated with the individual portion transgresses a second threshold value, the second threshold value being smaller than the first threshold value. In some cases, the memory controller, in response to determining that the degradation criterion of the individual portion is satisfied the second time, applies the memory operation on the first group of regions of the plurality of regions to test reliability of the first group of regions as part of performing a third PE cycle on the individual portion. The memory controller applies the memory operation on the second group of regions to test reliability of the second group of regions as part of performing a fourth PE cycle on the individual portion and re-selectively retires the individual portion based on results of testing the reliability of the first group of regions and the second group of regions across the third PE cycle and the fourth PE cycle.

In some examples, the memory controller divides the plurality of regions into a plurality of groups including the first group and the second group. The memory controller stores a table that associates the each of the plurality of groups with a respective PE cycle count. In some cases, the memory controller determines that a current PE cycle count of the individual portion corresponds to a first PE cycle count in the table. The memory controller identifies the first group of regions that is associated with the first PE cycle count in the table and applies the memory operation on the first group of regions in response to identifying the first group of regions that is associated with the first PE cycle count in the table. The memory controller stores a result of applying the memory operation on the first group of regions to test reliability of the first group in the table in association with the first group.

In some examples, the plurality of regions are equally divided into the plurality of groups.

Though various examples are described herein as being implemented with respect to a memory sub-system (e.g., a controller of the memory sub-system), some or all of the portions of an example can be implemented with respect to a host system, such as a software application or an operating system of the host system.

FIG. 1 illustrates an example computing environment 100 including a memory sub-system 110, in accordance with some examples of the present disclosure. The memory sub-system 110 can include media, such as memory components 112A to 112N (also hereinafter referred to as “memory devices”). The memory components 112A to 112N can be volatile memory devices, non-volatile memory devices, or a combination of such. The memory components 112A to 112N can be implemented by individual dies, such that a first memory component 112A can be implemented by a first memory die (or a first collection of memory dies) and a second memory component 112N can be implemented by a second memory die (or a second collection of memory dies). Each memory die can include a plurality of planes in which data can be stored or programmed. In some cases, the first memory component 112A can be implemented by a first SSD (or a first independently operable memory sub-system) and the second memory component 112N can be implemented by a second SSD (or a second independently operable memory sub-system). In some cases, each of the memory components 112A to 112N is associated with a respective one of LUN0 -N. For example, the first memory component 112A can be associated with a first LUN (referred to as LUN0) and the second memory component 112N can be associated with a second LUN (referred to as LUN1).

In some examples, the memory sub-system 110 is a storage system. A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to a memory system. The memory system can include one or more memory sub-systems 110. In some examples, the host system 120 is coupled to different types of memory sub-system 110. FIG. 1 illustrates one example of a host system 120 coupled to one memory sub-system 110. The host system 120 uses the memory sub-system 110, for example, to write (program) data to the memory sub-system 110 and read (retrieve) data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, etc.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL), a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory components 112A to 112N when the memory sub-system 110 is coupled with the host system 120 by the PCIe or CXL interface. The physical host interface can provide an interface for passing control, address, data, and other signals between the memory sub-system 110 and the host system 120.

The memory components 112A to 112N can include any combination of the different types of non-volatile memory components and/or volatile memory components and/or storage devices. An example of non-volatile memory components include a negative-and (NAND)-type flash memory. Each of the memory components 112A to 112N can include one or more arrays of memory cells such as single-level cells (SLCs) or multi-level cells (MLCs) (e.g., TLCs or QLCs). In some examples, a particular memory component 112 can include both an SLC portion and an MLC portion of memory cells. Each of the memory cells can store one or more bits of data (e.g., blocks) used by the host system 120. Although non-volatile memory components such as NAND-type flash memory are described, the memory components 112A to 112N can be based on any other type of memory, such as a volatile memory. In some examples, the memory components 112A to 112N can be, but are not limited to, random access memory (RAM), read-only memory (ROM), dynamic random access memory (DRAM), synchronous dynamic random access memory (SDRAM), phase change memory (PCM), magnetoresistive random access memory (MRAM), negative-or (NOR) flash memory, electrically erasable programmable read-only memory (EEPROM), and a cross-point array of non-volatile memory cells.

A cross-point array of non-volatile memory cells can perform bit storage based on a change of bulk resistance, in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. Furthermore, the memory cells of the memory components 112A to 112N can be grouped as memory pages or blocks that can refer to a unit of the memory component 112 used to store data. For example, a single first row that spans a first set of the pages or blocks of the memory components 112A to 112N can correspond to or be grouped as a first block stripe and a single second row that spans a second set of the pages or blocks of the memory components 112A to 112N can correspond to or be grouped as a second block stripe. A single block stripe can be associated with multiple LUNs (e.g., LUN0 -N).

The memory sub-system controller 115 can communicate with the memory components 112A to 112N to perform memory operations such as reading data, writing data, or erasing data at the memory components 112A to 112N and other such operations. The memory sub-system controller 115 can communicate with the memory components 112A to 112N to perform various memory management operations, such as enhancement operations, different scan rates, SG scan operations, different scan frequencies, different wear leveling, different read disturb management, garbage collection operations, different near miss ECC operations, and/or different dynamic data refresh. The SG scan operations can be performed to test reliability of a portion or the entirety of a block stripe or portion being tested. The SG scan operation can apply high and/or low VT voltages to the portion being tested to determine whether the output corresponds to an expected range and/or to modify a VT of the corresponding portions. A result of the SG scan operation can be indicative of failure of the portion being tested and if the portion fails the SG scan operation, the portion being tested and/or the entire block stripe that includes the portion being tested can be marked bad to prevent future writes to the portion and/or block stripe.

The memory sub-system controller 115 can include hardware, such as one or more integrated circuits and/or discrete components, a buffer memory, or a combination thereof. The memory sub-system controller 115 can be a microcontroller, special-purpose logic circuitry (e.g., a field programmable gate array (FPGA), an application specific integrated circuit (ASIC), etc.), or another suitable processor. The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120. In some examples, the local memory 119 can include memory registers storing memory pointers, fetched data, and so forth. The local memory 119 can also include read-only memory (ROM) for storing microcode. While the example memory sub-system 110 in FIG. 1 has been illustrated as including the memory sub-system controller 115, in another example of the present disclosure, a memory sub-system 110 may not include a memory sub-system controller 115, and can instead rely upon external control (e.g., provided by an external host, or by a processor 117 or controller separate from the memory sub-system 110).

In general, the memory sub-system controller 115 can receive commands or operations from the host system 120 and can convert the commands or operations into instructions or appropriate commands to achieve the desired access to the memory components 112A to 112N. In some examples, the commands or operations received from the host system 120 can specify configuration data for the memory components 112A to 112N. The configuration data can describe the lifetime (maximum) PEC values and/or reliability grades associated with different groups of the memory components 112A to 112N and/or different blocks within each of the memory components 112A to 112N. The configuration data can also include various manufacturing information for individual memory components of the memory components 112A to 112N. The manufacturing information can specify the reliability metrics/information associated with each memory component.

Depending on the example, the media operations manager 122 can comprise logic (e.g., a set of transitory or non-transitory machine instructions, such as firmware) or one or more components that causes the media operations manager 122 to perform operations described herein. The media operations manager 122 can comprise a tangible or non-tangible unit capable of performing operations described herein. Further details with regards to the operations of the media operations manager 122 are described below.

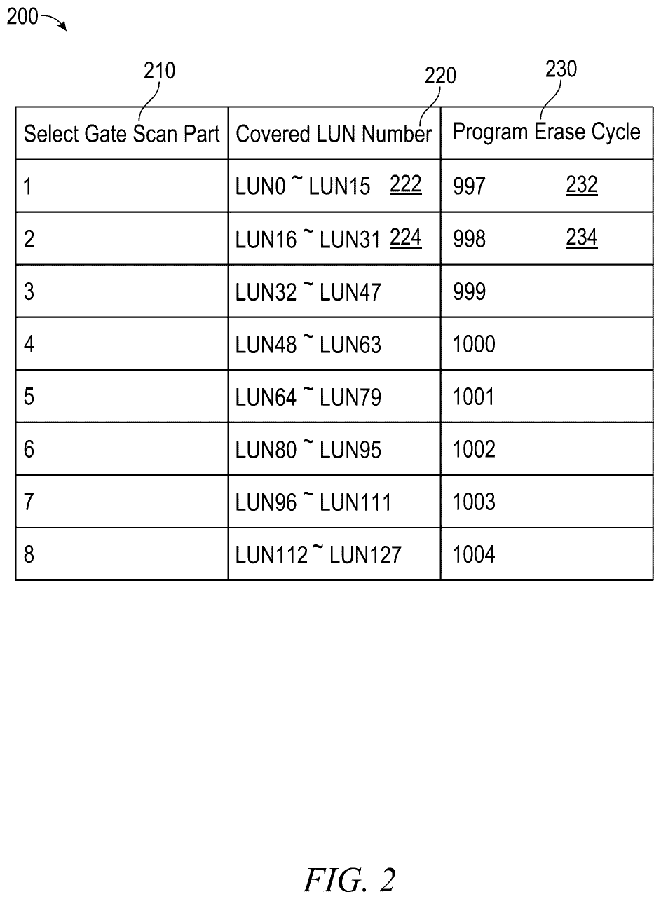

The configuration data can also store a table, such as the table 200, shown in FIG. 2. The table 200 can represent degradation criteria that is used to control when SG scan operations are performed on certain regions (e.g., LUNs) of individual portions (e.g., block stripes) of the set of memory components 112A to 112N. Specifically, the LUNs (regions) of each individual block stripe can be divided into many groups. Each group is associated with a SG scan part index 210. Each SG scan part index 210 can be associated with a respective group of regions 220 and a respective degradation criterion 230. The respective degradation criterion 230 can represent a PE cycle count that is used to control when a memory operation (e.g., SG scan operation) is performed on the regions identified by the respective group of regions 220 to test reliability of the group of regions 220.

For example, the individual block stripe can include or be associated with 128 regions (e.g., LUNs0-127). In such cases, the regions can be equally or unequally divided and distributed across a certain quantity or number of groups (e.g., eight groups). The number of groups can be specified by the configuration and can be computed based on the total amount of additional delay that can be encountered when performing erase or garbage collection operations (e.g., individual PE cycle operations) on a portion of the set of memory components 112A to 112N. The smaller the number of groups the larger the delay that is encountered during the PE cycle operations. The larger the number of groups the shorter the delay that is encountered during the PE cycle operations but the longer it takes to determine whether or not the portion (e.g., block stripe) of the set of memory components 112A to 112N needs to be retired (e.g., marked as bad to prevent future writes).

For example, a first group (identified by a first index) can include or be associated with a first group of regions 222 (e.g., LUN0 -LUN15). The first group of regions 222 can be associated with a first threshold value 232 (representing a first quantity or number of PE cycles). As an example, the first threshold value 232 can be 997. When the media operations manager 122 receives a request to erase the individual block stripe (e.g., as part of garbage collection operations or in response to a request from the host system 120), the media operations manager 122 accesses the table 200. The media operations manager 122 obtains a current PE cycle count associated with the individual portion (e.g., an individual block stripe). The media operations manager 122 determines whether the current PE cycle count corresponds to any threshold value specified in the degradation criterion 230.

For example, the media operations manager 122 can determine that the current PE cycle count is 900. The media operations manager 122 can determine that the current PE cycle count fails to match any threshold value specified in the degradation criterion 230. In such cases, the media operations manager 122 performs or completes the PE cycle (e.g., copies data stored in the portion to a free block in the free block pool and erases the portion and returns the erased portion to a free block pool). At a later time, the media operations manager 122 can receive a request to erase or perform a PE cycle for the individual portion and, in response, can determine that the current PE cycle count is 997. The media operations manager 122 can determine that the current PE cycle count of 997 corresponds to or transgresses the first threshold value 232 (e.g., 997). In response, the media operations manager 122 can perform a memory operation (e.g., an SG scan operation) to test a group of regions of the individual portion (the individual block stripe) that are included in the first group of regions 222 (e.g., LUNs0-15) associated with the first threshold value 232. Namely, the media operations manager 122, as part of performing the PE cycle on the individual portion, can also perform SG scan operations on some but not all of the regions (e.g., some of the LUNs of the portion) to test reliability of the regions (e.g., LUN0-15).

The media operations manager 122 can determine results of the test and can store the results of the test of reliability in association with the first group of regions 222 in the table 200. The media operations manager 122 can, after completing testing the first group of regions 222 for reliability, complete the PE cycle operations and place the individual portion in the free block pool. The media operations manager 122 can also increment the current PE cycle count associated with the individual portion (e.g., from 997 to 998). The individual portion can be programmed with new data at a later time. The media operations manager 122 can then receive a request to erase the individual portion again (e.g., to perform another PE cycle on the individual portion).

The media operations manager 122 can determine that the current PE cycle count of 998 corresponds to or transgresses a second threshold value 234 (e.g., 998). In response, the media operations manager 122 can perform a memory operation (e.g., an SG scan operation) to test a group of regions of the individual portion (the individual block stripe) that are included in a second group of regions 224 (e.g., LUNs16-31) associated with the second threshold value 234. Namely, the media operations manager 122, as part of performing the additional PE cycle on the individual portion, can also perform SG scan operations on some but not all of the regions (e.g., some of the LUNs of the portion) to test reliability of the regions (e.g., LUN16-31).

The media operations manager 122 can determine results of the test and can store the results of the test of reliability in association with the second group of regions 224 in the table 200. The media operations manager 122 can, after completing testing the second group of regions 224 for reliability, complete the additional PE cycle operations and place the individual portion in the free block pool. The media operations manager 122 can also increment the current PE cycle count associated with the individual portion (e.g., from 998 to 999).

The media operations manager 122 can continue testing different groups of regions of the individual portion at different PE cycles until all or a threshold quantity or number of groups have been tested. For example, the media operations manager 122 can determine when the last group of regions has been tested as part of the PE cycle operations. Namely, the media operations manager 122 can determine that the group of regions corresponding to LUN112-127 represents the last group of regions tested for reliability, such as based on the SG scan operations. In response, the media operations manager 122 can, prior to completing the PE cycle for the individual portion and returning the individual portion to the free block pool, obtain the test results stored in the table 200 for each of the group of regions 220.

In some examples, the media operations manager 122 can determine whether all of the test results or a specified portion of the test results (e.g., more than 50 percent) indicate that the group of regions being tested failed the test or failed the SG scan operations. This indicates that the individual portion that includes the group of regions 220 in the aggregate failed the SG scan operations. In such cases, the media operations manager 122 marks the individual portion as a bad block to prevent future writes to the individual portion.

In some examples, the media operations manager 122 can determine whether all of the test results or a specified portion of the test results (e.g., more than 50 percent) indicate that the group of regions being tested passed the test or passed the SG scan operations. This indicates that the individual portion that includes the group of regions 220 in the aggregate pass the SG scan operations successfully. In such cases, the media operations manager 122 completes the PE cycle on the individual portion and returns the individual portion to the free block pool.

In some examples, the table 200 stores multiple thresholds as part of the degradation criterion 230 for each group of regions 220. For example, the first group of regions 222 can be associated with the first threshold value 232 and additional thresholds that are greater than the first threshold value 232 and each other by a specified amount (e.g., 200). For example, the first threshold value 232 can be a value of 997, a first additional threshold can be a value of 1197, and a second additional threshold can be a value of 1397, and so forth. The first group of regions 224 can be associated with the second threshold value 234 and additional thresholds that are greater than the second threshold value 234 and each other by the specified amount (e.g., 200). For example, the second threshold value 234 can be a value of 998, a first additional threshold can be a value of 1198, and a second additional threshold can be a value of 1398, and so forth. This way, the media operations manager 122 can again test reliability of the group of regions 220 when the PE cycle count of the individual portion reaches one of the additional thresholds.

Namely, the groups of regions of the individual portion can initially be tested for reliability (e.g., by performing the SG scan operations) across multiple PE cycles when a first threshold PE cycle count is reached (e.g., 997). Then, if the individual potion is determined to pass the test of reliability, the individual portion is again tested for reliability (e.g., by performing the SG scan operations) across multiple PE cycles when a second threshold PE cycle count is reached (e.g., 1197). The media operations manager 122 can again selectively control whether the individual portion is placed back in the free block pool or marked bad based on results of testing each of the regions of the multiple groups of regions of the individual portion across the multiple PE cycles.

In some examples, the commands or operations received from the host system 120 can include a write/read command, which can specify or identify an individual memory component in which to program/read data. Based on the memory component specified by the write/read command, the memory sub-system controller 115 can program/read the data into/from one or more of the memory components 112A to 112N. The memory sub-system controller 115 can be responsible for other memory management operations, such as wear leveling operations, garbage collection operations, error detection and error-correcting code (ECC) operations, encryption operations, caching operations, and address translations. The memory sub-system controller 115 can further include host interface circuitry to communicate with the host system 120 via the physical host interface. The host interface circuitry can convert the commands received from the host system 120 into command instructions to access the memory components 112A to 112N as well as convert responses associated with the memory components 112A to 112N into information for the host system 120.

The memory sub-system 110 can also include additional circuitry or components that are not illustrated. In some examples, the memory sub-system 110 can include a cache or buffer (e.g., DRAM or other temporary storage location or device) and address circuitry (e.g., a row decoder and a column decoder) that can receive an address from the memory sub-system controller 115 and decode the address to access the memory components 112A to 112N.

The memory devices can be raw memory devices (e.g., NAND), which are managed externally, for example, by an external controller (e.g., memory sub-system controller 115). The memory devices can be managed memory devices (e.g., managed NAND), which are raw memory devices combined with a local embedded controller (e.g., local media controllers) for memory management within the same memory device package. Any one of the memory components 112A to 112N can include a media controller (e.g., media controller 113A and media controller 113N) to manage the memory cells of the memory component (e.g., to perform one or more memory management operations), to communicate with the memory sub-system controller 115, and to execute memory requests (e.g., read or write) received from the memory sub-system controller 115.

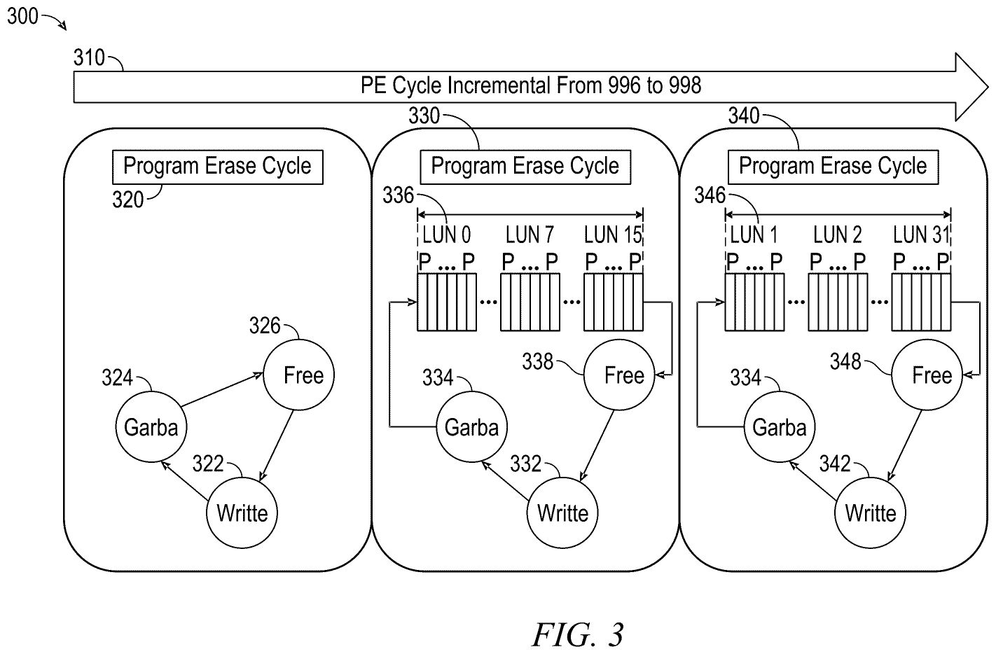

FIG. 3 is a block diagram of an example of a timing diagram 300 of the adaptive media management operations, in accordance with some implementations of the present disclosure. The timing diagram 300 shows how SG scan operations are selectively performed on certain groups of regions of an individual block stripe or portion of the set of memory components 112A to 112N across multiple PE cycles 310. Specifically, the media operations manager 122 can receive a request to erase an individual portion (e.g., an individual block stripe) of the set of memory components 112A to 112N. In response, the media operations manager 122 performs a first PE cycle 320 on the individual portion. For example, the media operations manager 122 can generate or receive the request to erase the individual portion as part of garbage collection operations 324. The media operations manager 122 can obtain a current PE cycle count associated with the individual portion.

The media operations manager 122 can determine if the current PE cycle count fails to correspond or match any PE cycle count thresholds stored in the table 200. Namely, the current PE cycle count may be determined to not match any of the degradation criterion 230 stored in the table 200. In such cases, after completing the garbage collection operations 324, the media operations manager 122 places the individual portion in the free block pool 326 and increments the PE cycle count associated with the individual portion from 996 to 997.

The media operations manager 122 can receive a request to program data to the individual portion that is in the free block pool 326 in operation 322. In response, the media operations manager 122 retrieves the individual portion from the free block pool 326 and stores the data in the individual portion. At a later time, the media operations manager 122 can receive a request to perform a second PE cycle 330 on the individual portion. For example, the media operations manager 122 can generate or receive the request to erase the individual portion as part of garbage collection operations 334. The media operations manager 122 can obtain a current PE cycle count associated with the individual portion. The media operations manager 122 can determine that the current PE cycle count of the individual portion corresponds to the first threshold value 232.

In such cases, prior to returning the individual portion to the free block pool 338, the media operations manager 122 performs a memory operation (e.g., SG scan operation) on a subset or group of regions of the individual portion. The group of regions on which the memory operation is performed is associated with the first threshold value 232 in the table 200. Specifically, the media operations manager 122 can perform the memory operation on a first group of regions 336 (e.g., LUNs0-15) of the individual portion. After completing the memory operation to test reliability of the first group of regions 336, the media operations manager 122 stores results of the test (e.g., in the table 200) and returns the individual portion to the free block pool 338.

The media operations manager 122 can receive a request to program data to the individual portion that is in the free block pool 338 in operation 332. In response, the media operations manager 122 retrieves the individual portion from the free block pool 338 and stores the data in the individual portion. At a later time, the media operations manager 122 can receive a request to perform a third PE cycle 340 on the individual portion. For example, the media operations manager 122 can generate or receive the request to erase the individual portion as part of garbage collection operations 344. The media operations manager 122 can obtain a current PE cycle count associated with the individual portion. The media operations manager 122 can determine that the current PE cycle count of the individual portion corresponds to the second threshold value 234 (table 200 in FIG. 2.).

In such cases, prior to returning the individual portion to the free block pool 348, the media operations manager 122 performs a memory operation (e.g., SG scan operation) on a subset or group of regions of the individual portion. The group of regions on which the memory operation is performed is associated with the second threshold value 234 in the table 200. Specifically, the media operations manager 122 can perform the memory operation on a second group of regions 346 (e.g., LUNs1-31) of the individual portion. After completing the memory operation to test reliability of the second group of regions 346, the media operations manager 122 stores results of the test (e.g., in the table 200) and returns the individual portion to the free block pool 348. The media operations manager 122 can receive a request to program data to the individual portion that is in the free block pool 348 in operation 342. The media operations manager 122 continues performing this sequence of operations until all of the groups of regions of the individual portion (or a certain quantity or number of groups of regions) are tested for reliability, such as based on the SG scan operations. At that point, the media operations manager 122 can selectively retire (e.g., determine whether to mark the individual portion as a bad block to prevent future writes to the individual portion) based on results of performing the test for reliability on the groups of regions across the multiple PE cycles 310.

For example, the media operations manager 122 can determine whether all of the test results or a specified portion of the test results (e.g., more than 50 percent) indicate that the group of regions being tested failed the test or failed the SG scan operations. This indicates that the individual portion that includes the group of portions in the aggregate failed the SG scan operations. In such cases, the media operations manager 122 marks the individual portion as a bad block to prevent future writes to the individual portion. In some examples, the media operations manager 122 can determine whether all of the test results or a specified portion of the test results (e.g., more than 50 percent) indicate that the group of regions being tested passed the test or passed the SG scan operations. This indicates that the individual portion that includes the group of portions in the aggregate pass the SG scan operations successfully. In such cases, the media operations manager 122 completes the PE cycle on the individual portion and returns the individual portion to the free block pool.

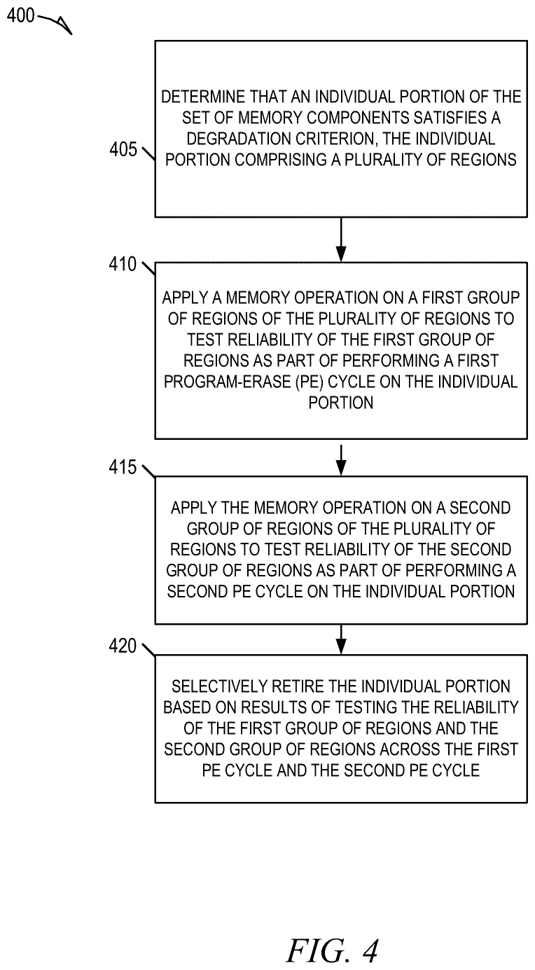

FIG. 4 is a flow diagram of an example method 400 for performing adaptive media management operations, in accordance with some implementations of the present disclosure. The method 400 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method 400 is performed by the media operations manager 122 of FIG. 1. Although the processes are shown in a particular sequence or order, unless otherwise specified, the order of the processes can be modified. Thus, the illustrated examples should be understood only as examples, and the illustrated processes can be performed in a different order, and some processes can be performed in parallel. Additionally, one or more processes can be omitted in various examples. Thus, not all processes are required in every example. Other process flows are possible.

Referring now to FIG. 4, the method 400 (or process) begins at operation 405, with a media operations manager 122 of a memory sub-system (e.g., memory sub-system 110) determining that an individual portion of a set of memory components satisfies a degradation criterion, the individual portion comprising a plurality of regions. Then, at operation 410, the media operations manager 122 applies a memory operation on a first group of regions of the plurality of regions to test reliability of the first group of regions as part of performing a first program-erase (PE) cycle on the individual portion and, at operation 415, applies the memory operation on a second group of regions of the plurality of regions to test reliability of the second group of regions as part of performing a second PE cycle on the individual portion. At operation 420, the media operations manager 122 selectively retires the individual portion based on results of testing the reliability of the first group of regions and the second group of regions across the first PE cycle and the second PE cycle.

In view of the disclosure above, various examples are set forth below. It should be noted that one or more features of an example, taken in isolation or combination, should be considered within the disclosure of this application.

Example 1. A system comprising: a set of memory components of a memory sub-system; and at least one processing device operatively coupled to the set of memory components, the at least one processing device being configured to perform operations comprising: determining that an individual portion of the set of memory components satisfies a degradation criterion, the individual portion comprising a plurality of regions; applying a memory operation on a first group of regions of the plurality of regions to test reliability of the first group of regions as part of performing a first program-erase (PE) cycle on the individual portion; applying the memory operation on a second group of regions of the plurality of regions to test reliability of the second group of regions as part of performing a second PE cycle on the individual portion; and selectively retiring the individual portion based on results of testing the reliability of the first group of regions and the second group of regions across the first PE cycle and the second PE cycle.

Example 2. The system of Example 1, the operations comprising: receiving a request to erase data stored in the individual portion; obtaining an PE cycle count associated with the individual portion in response to receiving the request; determining that the PE cycle count transgresses a threshold value; and in response to determining that the PE cycle count transgresses the threshold value, determining that the individual portion satisfies the degradation criterion.

Example 3. The system of any one of Examples 1-2, the operations comprising: tracking which regions of the plurality of regions have been tested for reliability across multiple PE cycles.

Example 4. The system of any one of Examples 1-3, the operations comprising: determining that the reliability of the first group of regions and the second group of regions represents failure of the first group of regions and the second group of regions.

Example 5. The system of Example 4, the operations comprising: in response to determining that the reliability of the first group of regions and the second group of regions represents failure, preventing data from being written to the individual portion.

Example 6. The system of any one of Examples 1-5, the operations comprising: determining that the reliability of a threshold quantity of groups of the plurality of regions represents failure; and in response to determining that the reliability of a threshold quantity of groups of the plurality of regions represents failure, preventing data from being written to the individual portion.

Example 7. The system of any one of Examples 1-6, wherein the individual portion comprises an individual block stripe, and wherein the plurality of regions comprises a plurality of logical unit numbers (LUNs) each associated with a respective collection of planes.

Example 8. The system of Example 7, wherein a first LUN of the plurality of LUNs corresponds to a first memory die, and wherein a second LUN of the plurality of LUNs corresponds to a second memory die.

Example 9. The system of any one of Examples 1-8, wherein the memory operation is applied to the first group in response to receiving a first request to erase the individual portion, the operations comprising: placing the individual portion in a free block pool to allow data to be written to the individual portion in response to applying the memory operation on the first group of regions to test reliability of the first group of regions; programming data to the individual portion that has been placed in the free block pool; receiving a second request to erase the individual portion after programming the data to the individual portion that has been placed in the free block pool, the second request being received after the first request to erase the individual portion; and applying the memory operation on the second group of regions to test reliability of the second group of regions in response to receiving the request to erase the individual portion.

Example 10. The system of Example 9, wherein the first request and the second request are generated as part of garbage collection operations.

Example 11. The system of any one of Examples 1-10, wherein the memory operation comprises a select gate scan operation.

Example 12. The system of any one of Examples 1-11, the operations comprising: determining that the results of testing the reliability of the first group of regions and the second group of regions indicate that the individual portion passes the reliability; and after performing a threshold number of additional PE cycles on the individual portion, determining that the degradation criterion is satisfied again.

Example 13. The system of Example 12, the operations comprising: determining that the degradation criterion of the individual portion is satisfied a first time in response to determining that a PE cycle count associated with the individual portion transgresses a first threshold value; and determining that the degradation criterion of the individual portion is satisfied a second time in response to determining that an updated PE cycle count associated with the individual portion transgresses a second threshold value, the second threshold value being smaller than the first threshold value.

Example 14. The system of Example 13, the operations comprising: in response to determining that the degradation criterion of the individual portion is satisfied the second time, applying the memory operation on the first group of regions of the plurality of regions to test reliability of the first group of regions as part of performing a third PE cycle on the individual portion; applying the memory operation on the second group of regions to test reliability of the second group of regions as part of performing a fourth PE cycle on the individual portion; and re-selectively retiring the individual portion based on results of testing the reliability of the first group of regions and the second group of regions across the third PE cycle and the fourth PE cycle.

Example 15. The system of any one of Examples 1-14, the operations comprising: dividing the plurality of regions into a plurality of groups comprising the first group and the second group; and storing a table that associates the each of the plurality of groups with a respective PE cycle count.

Example 16. The system of Example 15, the operations comprising: determining that a current PE cycle count of the individual portion corresponds to a first PE cycle count in the table; identifying the first group of regions that is associated with the first PE cycle count in the table; applying the memory operation on the first group of regions in response to identifying the first group of regions that is associated with the first PE cycle count in the table; and storing a result of applying the memory operation on the first group of regions to test reliability of the first group in the table in association with the first group.

Example 17. The system of any one of Examples 15-16, wherein the plurality of regions are equally divided into the plurality of groups.

Methods and computer-readable storage medium with instructions for performing any one of the above Examples.

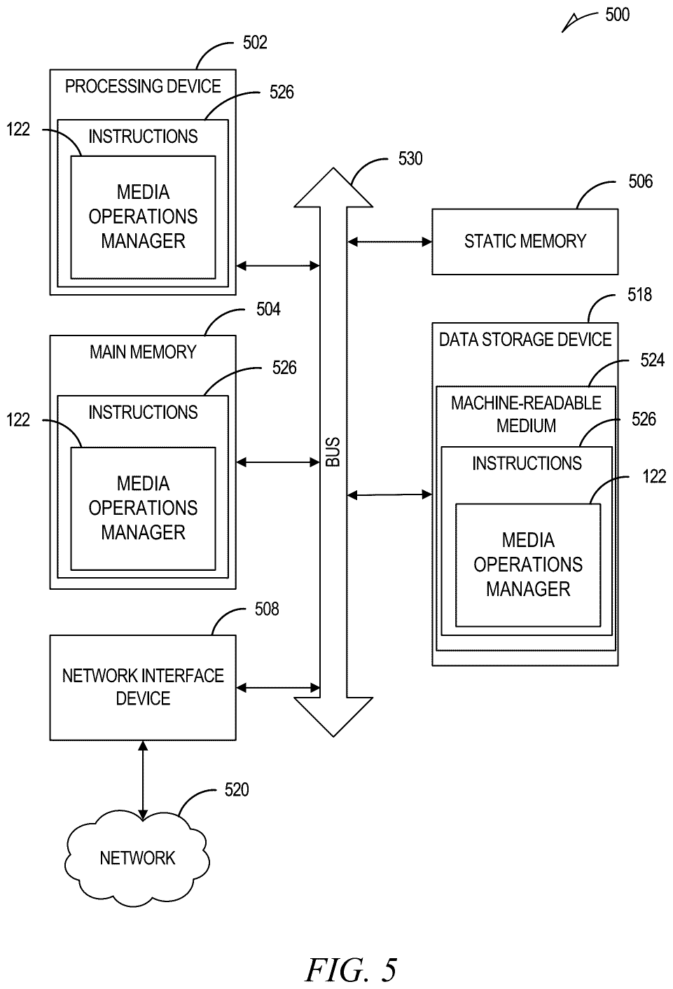

FIG. 5 illustrates an example machine in the form of a computer system 500 within which a set of instructions can be executed for causing the machine to perform any one or more of the methodologies discussed herein. In some examples, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the media operations manager 122 of FIG. 1). In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a network switch, a network bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a data storage system 518, which communicate with each other via a bus 530.

The processing device 502 represents one or more general-purpose processing devices such as a microprocessor, a central processing unit, or the like. More particularly, the processing device 502 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 502 can also be one or more special-purpose processing devices such as an application specific integrated circuit (ASIC), a field programmable gate array (FPGA), a digital signal processor (DSP), a network processor, or the like. The processing device 502 is configured to execute instructions 526 for performing the operations and steps discussed herein. The computer system 500 can further include a network interface device 508 to communicate over a network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one example, the instructions 526 implement functionality corresponding to the media operations manager 122 of FIG. 1. While the machine-readable storage medium 524 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to convey the substance of their work most effectively to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system's memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks; read-only memories (ROMs); random access memories (RAMs); erasable programmable read-only memories (EPROMs); EEPROMs; magnetic or optical cards; or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description above. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine-readable (e.g., computer-readable) storage medium such as a read-only memory (ROM), random access memory (RAM), magnetic disk storage media, optical storage media, flash memory components, and so forth.

In the foregoing specification, the disclosure has been described with reference to specific examples thereof. It will be evident that various modifications can be made thereto without departing from the broader scope of the disclosure as set forth in the following claims. The specification and drawings are, accordingly, to be regarded in an illustrative sense rather than a restrictive sense.

What is claimed is:

1. A system comprising:
a set of memory components of a memory sub-system; and
at least one processing device operatively coupled to the set of memory components, the at least one processing device being configured to perform operations comprising:
determining that an individual portion of the set of memory components satisfies a degradation criterion, the individual portion comprising a plurality of regions;
applying a memory operation on a first group of regions of the plurality of regions to test reliability of the first group of regions as part of performing a first program-erase (PE) cycle on the individual portion;
applying the memory operation on a second group of regions of the plurality of regions to test reliability of the second group of regions as part of performing a second PE cycle on the individual portion; and
selectively retiring the individual portion based on results of testing the reliability of the first group of regions and the second group of regions across the first PE cycle and the second PE cycle.

2. The system of claim 1, the operations comprising:
receiving a request to erase data stored in the individual portion;
obtaining an PE cycle count associated with the individual portion in response to receiving the request;
determining that the PE cycle count transgresses a threshold value; and
in response to determining that the PE cycle count transgresses the threshold value, determining that the individual portion satisfies the degradation criterion.

3. The system of claim 1, the operations comprising:
tracking which regions of the plurality of regions have been tested for reliability across multiple PE cycles.

4. The system of claim 1, the operations comprising:
determining that the reliability of the first group of regions and the second group of regions represents failure of the first group of regions and the second group of regions.

5. The system of claim 4, the operations comprising:
in response to determining that the reliability of the first group of regions and the second group of regions represents failure, preventing data from being written to the individual portion.

6. The system of claim 1, the operations comprising:
determining that the reliability of a threshold quantity of groups of the plurality of regions represents failure; and
in response to determining that the reliability of the threshold quantity of groups of the plurality of regions represents failure, preventing data from being written to the individual portion.

7. The system of claim 1, wherein the individual portion comprises an individual block stripe, and wherein the plurality of regions comprises a plurality of logical unit numbers (LUNs) each associated with a respective collection of planes.

8. The system of claim 7, wherein a first LUN of the plurality of LUNs corresponds to a first memory die, and wherein a second LUN of the plurality of LUNs corresponds to a second memory die.

9. The system of claim 1, wherein the memory operation is applied to the first group of regions in response to receiving a first request to erase the individual portion, the operations comprising:
placing the individual portion in a free block pool to allow data to be written to the individual portion in response to applying the memory operation on the first group of regions to test reliability of the first group of regions;
programming data to the individual portion that has been placed in the free block pool;
receiving a second request to erase the individual portion after programming the data to the individual portion that has been placed in the free block pool, the second request being received after the first request to erase the individual portion; and
applying the memory operation on the second group of regions to test reliability of the second group of regions in response to receiving the second request to erase the individual portion.

10. The system of claim 9, wherein the first request and the second request are generated as part of garbage collection operations.

11. The system of claim 1, wherein the memory operation comprises a select gate scan operation.

12. The system of claim 1, the operations comprising:
determining that the results of testing the reliability of the first group of regions and the second group of regions indicate that the individual portion passes the reliability; and
after performing a threshold number of additional PE cycles on the individual portion, determining that the degradation criterion is satisfied again.

13. The system of claim 12, the operations comprising:
determining that the degradation criterion of the individual portion is satisfied a first time in response to determining that a PE cycle count associated with the individual portion transgresses a first threshold value; and
determining that the degradation criterion of the individual portion is satisfied a second time in response to determining that an updated PE cycle count associated with the individual portion transgresses a second threshold value, the second threshold value being smaller than the first threshold value.

14. The system of claim 13, the operations comprising:
in response to determining that the degradation criterion of the individual portion is satisfied the second time, applying the memory operation on the first group of regions of the plurality of regions to test reliability of the first group of regions as part of performing a third PE cycle on the individual portion;
applying the memory operation on the second group of regions to test reliability of the second group of regions as part of performing a fourth PE cycle on the individual portion; and
re-selectively retiring the individual portion based on results of testing the reliability of the first group of regions and the second group of regions across the third PE cycle and the fourth PE cycle.

15. The system of claim 1, the operations comprising:
dividing the plurality of regions into a plurality of groups comprising the first group of regions and the second group of regions; and
storing a table that associates each of the plurality of groups with a respective PE cycle count.

16. The system of claim 15, the operations comprising:
determining that a current PE cycle count of the individual portion corresponds to a first PE cycle count in the table;
identifying the first group of regions that is associated with the first PE cycle count in the table;
applying the memory operation on the first group of regions in response to identifying the first group of regions that is associated with the first PE cycle count in the table; and
storing a result of applying the memory operation on the first group of regions to test reliability of the first group in the table in association with the first group.

17. The system of claim 15, wherein the plurality of regions is equally divided into the plurality of groups.

18. A method comprising:
determining that an individual portion of a set of memory components satisfies a degradation criterion, the individual portion comprising a plurality of regions;
applying a memory operation on a first group of regions of the plurality of regions to test reliability of the first group of regions as part of performing a first program-erase (PE) cycle on the individual portion;
applying the memory operation on a second group of regions of the plurality of regions to test reliability of the second group of regions as part of performing a second PE cycle on the individual portion; and
selectively retiring the individual portion based on results of testing the reliability of the first group of regions and the second group of regions across the first PE cycle and the second PE cycle.

19. The method of claim 18, comprising:
receiving a request to erase data stored in the individual portion;
obtaining an PE cycle count associated with the individual portion in response to receiving the request;
determining that the PE cycle count transgresses a threshold value; and
in response to determining that the PE cycle count transgresses the threshold value, determining that the individual portion satisfies the degradation criterion.

20. A non-transitory computer-readable storage medium comprising instructions that, when executed by at least one processing device, cause the at least one processing device to perform operations comprising:
determining that an individual portion of a set of memory components satisfies a degradation criterion, the individual portion comprising a plurality of regions;
applying a memory operation on a first group of regions of the plurality of regions to test reliability of the first group of regions as part of performing a first program-erase (PE) cycle on the individual portion;
applying the memory operation on a second group of regions of the plurality of regions to test reliability of the second group of regions as part of performing a second PE cycle on the individual portion; and
selectively retiring the individual portion based on results of testing the reliability of the first group of regions and the second group of regions across the first PE cycle and the second PE cycle.
